(19) United States
(12) Patent Application Publication
(10) Pub. No.: US 2018/0278209 A1
(43) Pub. Date: Sep. 27, 2018

(54) TEMPERATURE COMPENSATED OSCILLATOR AND ELECTRONIC DEVICE

(71) Applicant: SEIKO EPSON CORPORATION, Tokyo (JP)

(72) Inventors: Naohisa OBATA, Minowa-machi (JP); Takuya OWAKI, Shimosuwa-machi (JP)

(73) Assignee: SEIKO EPSON CORPORATION, Tokyo (JP)

(21) Appl. No.: 15/928,228

(22) Filed: Mar. 22, 2018

(30) Foreign Application Priority Data
Mar. 23, 2017 (JP) 2017-057472

(51) Int. Cl. H03B 5/04; H03B 5/32; H05K 7/20

(52) U.S. Cl. CPC H03B 5/04; H03B 5/32; H03B 2200/0012; H03B 2200/0008; H03B 2200/001; H05K 7/20136

(57) ABSTRACT

A temperature compensated oscillator includes a resonator element, an oscillation circuit, and a temperature compensation circuit. Assuming an observation time as T, an MTIE value at 0.1 s<τ≤1 s is 1.3 ns or less, an MTIE value at 1 s<τ≤10 s is 1.3 ns or less, an MTIE value at 10 s<τ≤100 s is 1.8 ns or less, an MTIE value at 100 s<τ≤1000 s is 2.9 ns or less, a TDEV value at 0.1 s<τ≤10 s is 47 ps or less, a TDEV value at 10 s<τ≤100 s is 65 ps or less, and a TDEV value at 100 s<τ≤1000 s is 94 ps or less.

### CROSS-REFERENCE TO RELATED APPLICATION

This nonprovisional application claims the benefit of Japanese Patent Application No. 2017-057472, filed Mar. 23, 2017, the entire disclosure of which is incorporated herein by reference.

### BACKGROUND

### 1. Technical Field

The present invention relates to a temperature compensated oscillator and an electronic device.

### 2. Related Art

A temperature compensated crystal oscillator (TCXO) has a quartz crystal resonator element and an integrated circuit (IC) for oscillating the resonator element, and the IC performs a temperature compensation for the deviation (frequency deviation) of an oscillation frequency of the quartz crystal resonator element from a desired frequency (nominal frequency) in a predetermined temperature range to obtain high frequency accuracy. Such temperature compensated crystal oscillator (TCXO) is, for example, disclosed in JP-A-2014-53663.

Since the temperature compensated crystal oscillator has high frequency stability, it is used for a communication device or the like which is desired to have high performance and high reliability.

There is a phase fluctuation in a frequency signal (the oscillation signal) which is output from an oscillator. Fluctuation that varies at a frequency lower than 10 Hz of the phase fluctuation in the frequency signal is called wander. The wander performance in a state of a constant temperature is defined in the ITU-T recommendation G.813.

However, it is difficult to operate the oscillator under an environment where the temperature is kept constant in practical use. Even though the oscillator is in compliance with the ITU-T recommendation G.813, there is a possibility that the sufficient performance of the oscillator cannot be obtained under a severe temperature environment, for example, in a case of being used for a car navigation apparatus or an instrument for a vehicle or in a case of being built in an apparatus that the temperature thereof is changed suddenly due to a fan operation or the like.

### SUMMARY

An advantage of some aspects of the invention is to provide a temperature compensated oscillator that can be used for an electronic device and a vehicle that are required to have high frequency stability even under the severe temperature environment. Another advantage of some aspects of the invention is to provide an electronic device including the temperature compensated oscillator described above.

The invention can be implemented as the following forms or application examples.

### Application Example 1

A temperature compensated oscillator according to this application example includes: a resonator element; an oscillation circuit; and a temperature compensation circuit, in a case where a temperature is constant at 25° C. from a measurement start to an elapsed time of 60 minutes, is raised from 25° C. to 85° C. at a heating rate of 1° C./min from an elapsed time of 60 minutes to 120 minutes, is constant at 85° C. from an elapsed time of 120 minutes to 125 minutes, is lowered from 85° C. to 25° C. at a cooling rate of 1° C./min from an elapsed time of 125 minutes to 185 minutes, is constant at 25° C. from an elapsed time of 185 minutes to 190 minutes, is lowered from 25° C. to −40° C. at the cooling rate of 1° C./min from an elapsed time of 190 minutes to 255 minutes, is constant at −40° C. from an elapsed time of 255 minutes to 260 minutes, is raised from −40° C. to 25° C. at the heating rate of 1° C./min from an elapsed time of 260 minutes to 325 minutes, and is constant at 25° C. from an elapsed time of 325 minutes to 385 minutes, assuming an observation time as τ, an MTIE value at 0.1 s<τ≤1 s is 1.3 ns or less, an MTIE value at 1 s<τ≤10 s is 1.3 ns or less, an MTIE value at 10 s<τ≤100 s is 1.8 ns or less, an MTIE value at 100 s<τ≤1000 s is 2.9 ns or less, a TDEV value at 0.1 s<τ≤10 s is 47 ps or less, a TDEV value at 10 s<τ≤100 s is 65 ps or less, and a TDEV value at 100 s<τ≤1000 s is 94 ps or less.

For example, various oscillation circuits such as the Pierce oscillation circuit, an inverter type oscillation circuit, the Colpitts oscillation circuit, the Hartley oscillation circuit may be configured by the resonator element and the oscillation circuit.

The temperature compensated oscillator according to this application example has the excellent wander performance even under an environment where a temperature is changed. Consequently, the oscillator according to Application Example 1 can be used for the electronic device and the vehicle that are required to have high frequency stability even under the severe temperature environment.

### Application Example 2

The temperature compensated oscillator according to the application example described above may further include a first container that accommodates the resonator element; and a second container that accommodates the first container, the oscillation circuit, and the temperature compensation circuit, and the first container may have a first base in which the resonator element is disposed and a first lid, and the first lid may be bonded to the second container.

In the temperature compensated oscillator according to this application example, since the first lid of the first container is bonded to the second container, it is possible to dispose an electronic component including the oscillation circuit and the temperature compensation circuit on the outer bottom surface of the first base of the first container. Consequently, the temperature difference between the resonator element and the electronic component can be reduced. Therefore, in the oscillator according to Application Example 2, it is possible to reduce an error in the temperature compensation by the temperature compensation circuit and to have the high frequency reliability.

### Application Example 3

In the temperature compensated oscillator according to the application example described above, the temperature compensation circuit may compensate for frequency temperature characteristics of the resonator element based on an output signal of a temperature sensor, the first base may have a first surface on which the resonator element is disposed and a second surface opposite to the first surface, and an electronic component including the oscillation circuit, the temperature compensation circuit, and the temperature sensor may be disposed on the second surface.

In the temperature compensated oscillator according to this application example, it is possible to reduce the temperature difference between the resonator element and the electronic component.

### Application Example 4

In the temperature compensated oscillator according to the application example described above, a terminal that is connected electrically to the resonator element may be disposed on the second surface.

In the temperature compensated oscillator according to this application example, it is possible to reduce a wire length between the oscillation circuit and the resonator element, so that the influence of a noise can be reduced.

### Application Example 5

In the temperature compensated oscillator according to the application example described above, the second container may have a second base and a second lid, and the resonator element may be positioned between the first lid and the second lid.

In the temperature compensated oscillator according to this application example, the first lid of the first container and the second lid of the second container can function as a shield for shielding the external noise, so that the influence of the noise with respect to the resonator element can be reduced.

### Application Example 6

In the temperature compensated oscillator according to the application example described above, a space inside the second container may be a vacuum.

In the temperature compensated oscillator according to this application example, since the space inside the second container is the vacuum, it is possible to reduce the influence of the temperature variation outside the second container on the electronic component and the resonator element.

### Application Example 7

An electronic device according to this application example includes the oscillator according to any one of the application examples described above and a cooling fan.

In the electronic device according to this application example, since the oscillator having the excellent wander performance even under an environment where a temperature is changed is included, even in a case where the oscillator is blown with the wind by an operation of the cooling fan, it is possible to realize the electronic device having high performance and high reliability.

### BRIEF DESCRIPTION OF THE DRAWINGS

The invention will be described with reference to the accompanying drawings, wherein like numbers reference like elements.

FIG. 1 is a perspective view schematically showing an oscillator according to an embodiment.

FIG. 2 is a cross-sectional view schematically showing the oscillator according to the embodiment.

FIG. 3 is a plan view schematically showing the oscillator according to the embodiment.

FIG. 4 is a bottom surface view schematically showing the oscillator according to the embodiment.

FIG. 5 is a plan view schematically showing a package base of the oscillator according to the embodiment.

FIG. 6 is a functional block diagram of the oscillator according to the embodiment.

FIG. 7 is a flowchart showing an example of a procedure of a method of manufacturing the oscillator according to the embodiment.

FIG. 8 is a diagram showing a measurement system for evaluating a wander performance.

FIG. 9 is a cross-sectional view schematically showing a configuration of a comparison sample.

FIG. 10 is a graph showing a temperature profile in a chamber.

FIG. 11 is a graph showing an evaluation result of the wander performance of the oscillator according to the embodiment.

FIG. 12 is a graph showing an evaluation result of the wander performance of the oscillator according to the embodiment.

FIG. 13 is a plan view schematically showing a package base of an oscillator according to a first modification example.

FIG. 14 is a cross-sectional view schematically showing an oscillator according to a third modification example.

FIG. 15 is a functional block diagram showing an example of a configuration of an electronic device according to the embodiment.

FIG. 16 is a diagram showing an example of the external appearance of the electronic device according to the embodiment.

FIG. 17 is a diagram showing an example of a vehicle according to the embodiment.

### DESCRIPTION OF EXEMPLARY EMBODIMENTS

Hereinafter, preferable embodiments of the invention will be described using drawings in detail. The embodiments described below do not unreasonably limit the contents of the invention described in the aspects. Not all of the configurations described below are necessarily essential components of the invention.

### 1. Oscillator

### 1.1. Configuration of Oscillator

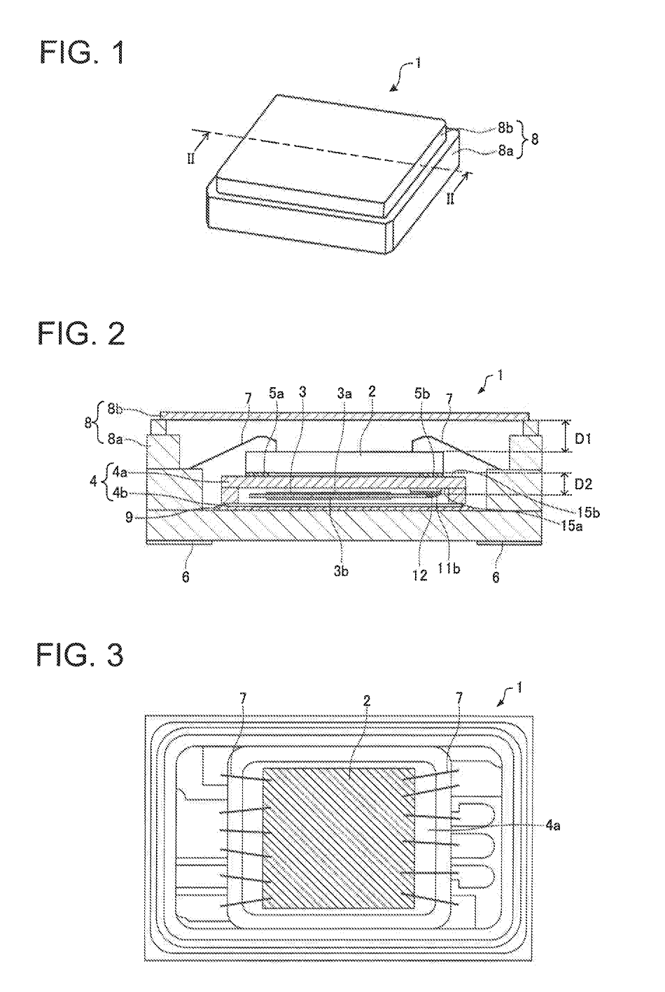

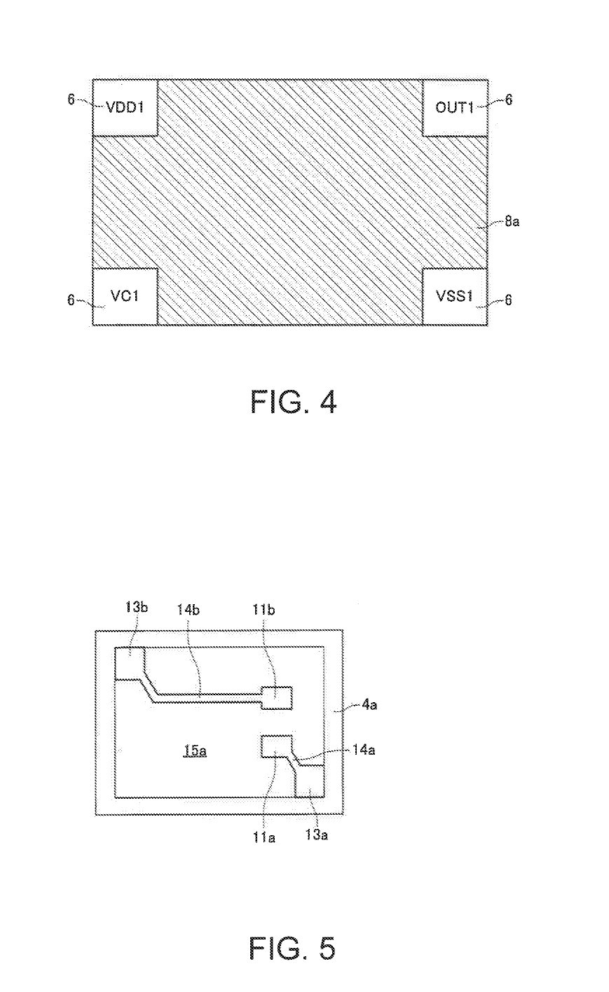

FIGS. 1 to 4 are views schematically showing an example of a configuration of an oscillator 1 according to an embodiment. FIG. 1 is a perspective view of the oscillator 1. FIG. 2 is a cross-sectional view taken along line II-II of FIG. 1. FIG. 3 is a top view of the oscillator 1. FIG. 4 is a bottom view of the oscillator 1. In FIG. 3, the illustration of a lid 8b is omitted for the sake of convenience.

As shown in FIGS. 1 to 4, the oscillator 1 is configured to have an integrated circuit (IC) 2 which is an electronic component, a resonator element 3, a package 4 as a first container, and a package 8 as a second container.

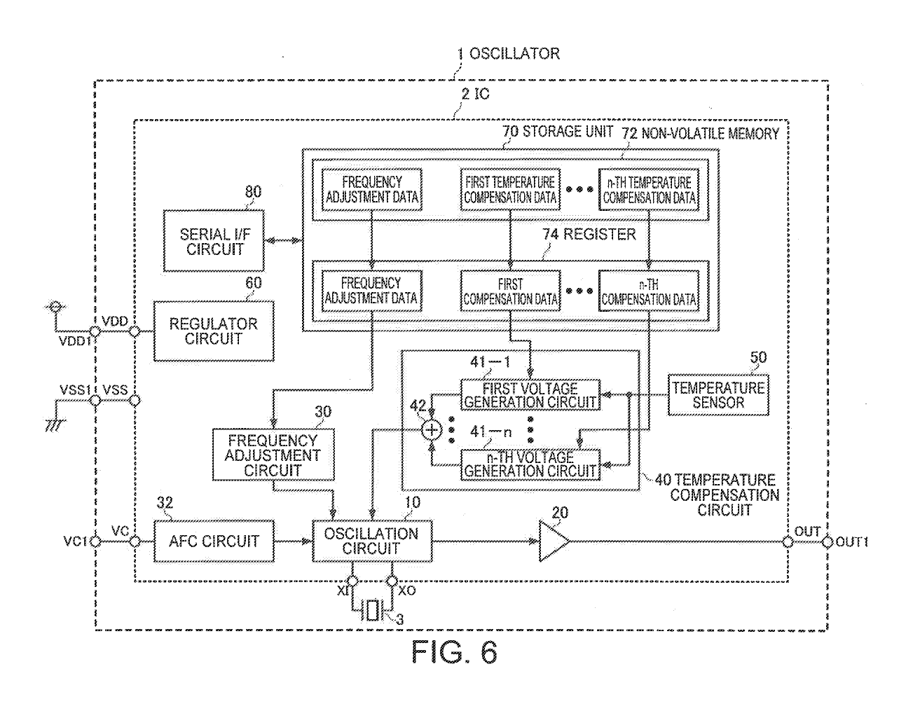

The integrated circuit (IC) 2 is accommodated in the package 8. The integrated circuit (IC) 2 is configured to have an oscillation circuit 10, a temperature compensation circuit 40, and a temperature sensor 50 (refer to FIG. 6) as described below.

As the resonator element 3, for example, a quartz crystal resonator element, a surface acoustic wave (SAW) resonator element, other piezoelectric resonator elements, a micro electro mechanical systems (MEMS) resonator element, or the like can be used. As a substrate material of the resonator element 3, it is possible to use a piezoelectric single crystal, such as quartz crystal, lithium tantalate, or lithium niobate, a piezoelectric material, such as a piezoelectric ceramic such as lead zirconate titanate, or a silicon semiconductor material. As excitation means of the resonator element 3, a piezoelectric effect may be used, or an electrostatic drive by a coulomb force may be used.

The resonator element 3 has respectively a metal excitation electrode 3a and a metal excitation electrode 3b on the front surface side and back surface side of the resonator element 3 (two surfaces in front-back relationship) and oscillates at a desired frequency (frequency required for the oscillator 1) corresponding to the mass of the resonator element 3 including the excitation electrode 3a and the excitation electrode 3b.

The package 4 includes a base 4a as a first base and a lid 4b as a first lid sealing the base 4a. The package 4 accommodates the resonator element 3. Specifically, the recessed portion is disposed in the base 4a, and the lid 4b covers the recessed portion to accommodate the resonator element 3. The resonator element 3 is disposed in a first surface 15a of the base 4a. A space in which the package 4 accommodates the resonator element 3 is, for example, the inert gas atmosphere such as nitrogen gas.

The material of the base 4a is not limited particularly. Various ceramics such as aluminum oxide can be used. The material of the lid 4b is not limited particularly. It is, for example, a metal such as nickel, cobalt, or an iron alloy (for example, Kovar). The lid 4b may be a plate-shaped member coated with the metal.

There may be a metal object for sealing between the base 4a and the lid 4b. The metal object may have a configuration that a metal film is disposed directly, for example, on a so-called seam ring made of a cobalt alloy for seam sealing or on the ceramic material configuring the base 4a.

FIG. 5 is a plan view schematically showing the base 4a of the package 4.

As shown in FIG. 5, electrode pads 11a and 11b, electrode pads 13a and 13b, and lead-out wires 14a and 14b are disposed in the first surface (bottom surface of the recessed portion of the base 4a and surface positioned inside the package 4 of the base 4a) 15a of the base 4a. The base 4a includes a plate-shaped base main body in which the electrode pads 11a and 11b are disposed and a frame body surrounding the first surface 15a.

The electrode pads 11a and 11b are connected electrically to the two excitation electrodes 3a and 3b of the resonator element 3, respectively. The resonator element 3 is bonded (adhered) to the electrode pads 11a and 11b by a connection member 12 such as a conductive adhesive.

The electrode pads 13a and 13b are connected electrically to two external terminals 5a and 5b (refer to FIG. 2) of the package 4, respectively. The electrode pad 13a and the electrode pad 13b are disposed diagonally to the first surface 15a of the base 4a.

The lead-out wire 14a is connected electrically to the electrode pad 11a and the electrode pad 13a. The lead-out wire 14b is connected electrically to the electrode pad 11b and the electrode pad 13b.

As shown in FIG. 2, the package 4 is bonded (adhered) to the package 8. Specifically, the lid 4b of the package 4 is bonded to a base 8a of the package 8. That is, the lid 4b is positioned on the bottom surface side of the recessed portion of the base 8a, and the base 4a is positioned on the lid 8b side. Accordingly, in the example shown in FIG. 2, the lid 4b is positioned on the lower side, and the base 4a is positioned on the upper side with the lid 8b side of the package 8 on the upper side and the base 8a side thereof on the lower side. The lid 4b and the base 8a are bonded (adhered) by a connection member 9 such as the conductive adhesive or an insulating adhesive. A method of bonding the lid 4b and the base 8a is not limited particularly.

At least a part of the surface contacting to the connection member 9 of the lid 4b may be in a rough state (rough surface). In the case, a bonded state with the connection member 9 is improved, and the impact resistance is enhanced. The rough surface is, for example, a state having unevenness by laser processing, and is coarse, for example, as compared with the surface of an accommodation space side on which such processing is not performed. The lid 4b may be warped so as to be protruded toward the resonator element 3. Consequently, it is possible to increase a gap between the lid 4b and the base 8a, and it is possible to reduce the heat exchange capacity between the lid 4b and the base 8a.

In the embodiment, as described above, since the lid 4b of the package 4 is bonded to the base 8a of the package 8, as shown in FIG. 2, the resonator element 3 is positioned between the lid 4b and the lid 8b. The resonator element 3 is positioned in a region where the lid 4b and the lid 8b overlap each other in a plan view (oscillator 1 is viewed from the top surface and from the perpendicular direction of the bottom surface of the base 8a).

The external terminals 5a and 5b connected electrically to the resonator element 3 are disposed on a second surface 15b of the base 4a. The two external terminals 5a and 5b of the package 4 are connected electrically to two terminals (XO terminal and XI terminal of FIG. 6 described below) of the integrated circuit (IC) 2, respectively.

The integrated circuit (IC) 2 is disposed on the base 4a of the package 4. Specifically, the integrated circuit (IC) 2 is disposed on the second surface (surface opposite side to the first surface 15a and outer bottom surface of the base 4a) 15b of the base 4a. That is, an oscillation circuit 10, a temperature compensation circuit 40, and a temperature sensor 50 (refer to FIG. 6) are disposed on the second surface 15b of the base 4a. The integrated circuit (IC) 2 may be bonded (adhered) to the base 4a with an adhesive, the silver paste, a metal bump, or the like.

As shown in FIG. 3, the integrated circuit (IC) 2 and the package 4 overlap in a plan view, and the integrated circuit (IC) 2 is directly mounted on the base 4a. In the manner, the integrated circuit (IC) 2 is bonded to the base 4a, so that the integrated circuit (IC) 2 and the resonator element 3 can be disposed close to each other. Consequently, since the heat generated in the integrated circuit (IC) 2 is conducted to the resonator element 3 in a short time, it is possible to reduce a temperature difference between the integrated circuit (IC) 2 and the resonator element 3.

For example, in the integrated circuit (IC) 2, at least a part of a surface in contact with an adhesive member (not shown) for bonding with the package 4 may be in a rough state (roughened surface). In the case, a bonded state with the adhesive member is improved, and the impact resistance and the heat exchange capacity are enhanced. The roughened surface is, for example, a state having unevenness such as a streak formed by grinding. The second surface 15b of the base 4a may be warped so as to be in a recessed state. When the recess by the warping overlaps with the integrated circuit (IC) 2, it is easy to store the adhesive member in the recess. Consequently, since a sufficient amount of the adhesive member can be disposed between the integrated circuit (IC) 2 and the base 4a, the adhesion therebetween is improved, and the heat exchange capacity between the integrated circuit (IC) 2 and the base 4a, that is, the integrated circuit (IC) 2 and the resonator element 3 is enhanced.

The package 8 includes the base 8a as a second base and the lid 8b as a second lid sealing the base 8a. The package 8 accommodates the package 4 in which the resonator element 3 is accommodated and the integrated circuit (IC) 2 in the same space. That is, the package 8 accommodates the package 4, the oscillation circuit 10, the temperature compensation circuit 40, and the temperature sensor 50 (refer to FIG. 6). Specifically, the recessed portion is disposed in the base 8a, and the lid 8b covers the recessed portion to accommodate the integrated circuit (IC) 2 and the package 4. The space where the package 8 accommodates the integrated circuit (IC) 2 and the package 4 is, for example, the inert gas atmosphere such as nitrogen gas.

There is a space between the inner surface of the package 8 and the package 4. In the shown example, the inner wall surface (inner side surface) of the base 8a is not in contact with the package 4, and the space (gap) is disposed therebetween. The lid 8b is not in contact with the package 4, and the space (gap) is disposed therebetween.

There is a space between the inner surface of the package 8 and the integrated circuit (IC) 2. In the shown example, the inner wall surface of the base 8a is not in contact with the integrated circuit (IC) 2, and the space (gap) is disposed therebetween. The lid 8b is not in contact with the integrated circuit (IC) 2, and the space (gap) is disposed therebetween.

The material of the base 8a is not limited particularly. Various ceramics such as aluminum oxide can be used. The material of the lid 8b is, for example, a metal. The material of the lid 8b may be, for example, the same material as the lid 4b or a different material. The lid 8b of the embodiment has a plate shape, and the area of the lid 8b is small as compared with a cap shape having a recess. Consequently, since the wind from the package lateral direction is received easily, it is possible to reduce the temperature variation due to the outside air. A sealing body is used for bonding the ceramic base 8a and lid 8b. The sealing body is a metal sealing body including a material such as cobalt alloy or gold, or a non-metal sealing body such as glass or resin.

In the oscillator 1, the distance D1 which is the shortest distance between the lid 8b of the package 8 and the integrated circuit (IC) 2 is larger than the distance D2 which is the shortest distance between the integrated circuit (IC) 2 and the resonator element 3. In the shown example, the distance D1 is the distance between the lower surface of the lid 8b and the upper surface of the integrated circuit (IC) 2, and the distance D2 is the distance between the lower surface of the integrated circuit (IC) 2 and the upper surface of the resonator element 3. As described above, the integrated circuit (IC) 2 is closer to the resonator element 3 than the lid 8b, so that the temperature difference between the integrated circuit (IC) 2 and the resonator element 3 can be reduced.

A wire (not shown) electrically connected to each external terminal 6 is disposed inside the base 8a or on the surface of the recessed portion, and each wire and each terminal of the integrated circuit (IC) 2 are bonded with a bonding wire 7 of gold or the like.

As shown in FIG. 4, on the back surface of the base 8a, there are provided with four external terminals 6 of an external terminal VDD 1 which is the power supply terminal, an external terminal VSS 1 which is the ground terminal, an external terminal VC 1 in which a signal for frequency control is input, and an external terminal OUT 1 which is the output terminal. A power supply voltage is supplied to the external terminal VDD 1, and the external terminal VSS 1 is grounded.

FIG. 6 is a functional block diagram of the oscillator 1. As shown in FIG. 6, the oscillator 1 is an oscillator including the resonator element 3 and the integrated circuit (IC) 2 for oscillating the resonator element 3.

In the integrated circuit (IC) 2, there are provided with the VDD terminal which is the power supply terminal, the VSS terminal which is the ground terminal, the OUT terminal which is the output terminal, the VC terminal in which the signal for frequency control is input, and an XI terminal and an XO terminal which are connection terminals with the resonator element 3. The VDD terminal, the VSS terminal, the OUT terminal, and the VC terminal are exposed to the surface of the integrated circuit (IC) 2, and connected to the external terminals of VDD 1, VSS 1, OUT 1, and VC 1 disposed in the package 8, respectively. The XI terminal is connected to one end (one terminal) of the resonator element 3, and the XO terminal is connected to the other end (the other terminal) of the resonator element 3.

In the embodiment, the integrated circuit (IC) 2 is configured to have the oscillation circuit 10, an output circuit 20, a frequency adjustment circuit 30, an automatic frequency control (AFC) circuit 32, the temperature compensation circuit 40, the temperature sensor 50, a regulator circuit 60, a storage unit 70, and a serial interface (I/F) circuit 80. The integrated circuit (IC) 2 may have a configuration in which a part of above elements is omitted or changed, or another element is added.

The regulator circuit 60 generates the power supply voltage of a part or all of the oscillation circuit 10, the frequency adjustment circuit 30, the AFC circuit 32, the temperature compensation circuit 40, and the output circuit 20, or a constant voltage which becomes the reference voltage based on the power supply voltage VDD (positive voltage) supplied from the VDD terminal.

The storage unit 70 has a non-volatile memory 72 and a register 74 and is configured to be capable of reading and writing (hereinafter read/write) with respect to the non-volatile memory 72 or the register 74 from the external terminal through a serial interface circuit 80. In the embodiment, since the terminal of the integrated circuit (IC) 2 connected to the external terminals of the oscillator 1 is only four of VDD, VSS, OUT, and VC, for example, when the voltage of VDD terminal is higher than a threshold voltage, the serial interface circuit 80 receives a clock signal input from the VC terminal and a data signal input from the OUT terminal, and performs read/write of data with respect to the non-volatile memory 72 or the register 74.

The non-volatile memory 72 is a storage unit for storing various control data and may be, for example, various rewritable non-volatile memory such as the electrically erasable programmable read-only memory (EEPROM) or the flash memory, or various non-rewritable non-volatile memory such as the one time programmable read only memory (one time PROM).

The non-volatile memory 72 stores frequency adjustment data for controlling the frequency adjustment circuit 30 and temperature compensation data (first compensation data, . . . , n-th compensation data) for controlling the temperature compensation circuit 40. Further, the non-volatile memory 72 stores data (not shown) for respectively controlling the output circuit 20 and the AFC circuit 32.

The frequency adjustment data is data for adjusting the frequency of the oscillator 1. When the frequency of the oscillator 1 deviates from a desired frequency, the frequency adjustment data is rewritten, so that the frequency of the oscillator 1 can be adjusted finely so as to be close to the desired frequency.

The temperature compensation data (first compensation data, . . . , n-th compensation data) is data, which is calculated in a temperature compensation adjustment step of the oscillator 1, for correction of the frequency-temperature characteristics of the oscillator 1. For example, the data may be first to n-th coefficient value corresponding to each order component of the frequency-temperature characteristics of the resonator element 3. As the maximum order n of the temperature compensation data, a value capable of cancelling the frequency-temperature characteristics of the resonator element 3, further correcting the influence of the temperature characteristics of the integrated circuit (IC) 2 is selected. For example, the n may be an integer larger than principal order of the frequency-temperature characteristics of the resonator element 3. For example, when the resonator element 3 is an AT cut quartz crystal resonator element, since the frequency-temperature characteristics shows a cubic curve and the principal order is three, an integer larger than 3 (for example, five or six) may be selected as the n. The temperature compensation data may include compensation data of all orders of first to n-th orders or may include compensation data of only a part of first to n-th orders.

When the power supply of the integrated circuit (IC) 2 is turned on (when a voltage of the VDD terminal rises from 0 V to a desired voltage), each data stored in the non-volatile memory 72 is transmitted from the non-volatile memory 72 to the register 74 and is saved in the register 74. The frequency adjustment data stored in the register 74 is input into the frequency adjustment circuit 30, the temperature compensation data (first compensation data, . . . , n-th compensation data) stored in the register 74 is input into the temperature compensation circuit 40, and data for control stored in the register 74 is input into the output circuit 20 and the AFC circuit 32.

In a case where the non-volatile memory 72 is non-rewritable, at the time of inspecting the oscillator 1, each data is written directly into each bit of the register 74 in which each data transmitted from the non-volatile memory 72 is stored from the external terminal through the serial interface circuit 80, so that the oscillator 1 is adjusted so as to satisfy a desired characteristics, and each adjusted data is written finally into the non-volatile memory 72. In a case where the non-volatile memory 72 is rewritable, at the time of inspecting the oscillator 1, each data may be written into the non-volatile memory 72 from the external terminal through the serial interface circuit 80. However, since it takes time to rewrite into the non-volatile memory 72, at the time of inspecting the oscillator 1, in order to reduce the inspection time, each data may be written directly into each bit of the register 74 from the external terminal through the serial interface circuit 80, and each adjusted data is written finally into the non-volatile memory 72.

The oscillation circuit 10 amplifies the output signal of the resonator element 3 and feeds the amplified signal back to the resonator element 3, so that the resonator element 3 is oscillated and an oscillation signal based on the oscillation of the resonator element 3 is output. For example, an oscillation stage current of the oscillation circuit 10 may be controlled by control data stored in the register 74.

The frequency adjustment circuit 30 generates a voltage corresponding to the frequency adjustment data stored in the register 74 and applies the generated voltage to one end of a variable capacitance element (not shown) that functions as a load capacitor of the oscillation circuit 10. Consequently, the oscillation frequency (reference frequency) of the oscillation circuit 10 under conditions that a temperature becomes a predetermined temperature (for example, 25° C.) and a voltage of the VC terminal becomes a predetermined voltage (for example, VDD/2) is controlled (adjusted finely) so as to substantially be the desired frequency.

The AFC circuit 32 generates a voltage corresponding to the voltage of the VC terminal and applies the generated voltage to one end of the variable capacitance element (not shown) that functions as the load capacitor of the oscillation circuit 10. Consequently, the oscillation frequency of the oscillation circuit 10 (oscillation frequency of resonator element 3) is controlled based on the voltage value of the VC terminal. For example, the gain of the AFC circuit 32 may be controlled by the control data stored in the register 74.

The temperature sensor 50 measures the temperature. The temperature sensor 50 is a temperature sensitive element that outputs a signal corresponding to the surrounding temperature (for example, a voltage corresponding to the temperature). The temperature sensor 50 may be a positive polarity sensor having a higher output voltage as the temperature is higher or may be a negative polarity sensor having a lower output voltage as the temperature is higher. As the temperature sensor 50, it is preferable that the output voltage of the sensor linearly changes as much as possible with respect to the temperature change within a desired temperature range where an operation of the oscillator 1 is guaranteed.

The temperature compensation circuit 40 compensates for the frequency-temperature characteristic of the resonator element 3 based on the output signal of the temperature sensor 50. The temperature compensation circuit 40 receives the output signal from the temperature sensor 50, generates a voltage for correcting the frequency-temperature characteristic of the resonator element 3 (temperature compensation voltage), and applies the generated voltage to one end of the variable capacitance element (not shown) that functions as the load capacitor of the oscillation circuit 10. Consequently, the oscillation frequency of the oscillation circuit 10 is controlled so as to substantially be constant irrespective of the temperature. In the embodiment, the temperature compensation circuit 40 is configured to have a first voltage generation circuit 41-1 to an n-th voltage generation circuit 41-n and an addition circuit 42.

The first voltage generation circuit 41-1 to the n-th voltage generation circuit 41-n respectively receive the output signal from the temperature sensor 50, generates a first compensation voltage to an n-th compensation voltage for compensating a first component to an n-th component of the frequency-temperature characteristics corresponding to first compensation data to n-th compensation data stored in the register 74.

The addition circuit 42 adds the first compensation voltage to the n-th compensation voltage respectively generated by the first voltage generation circuit 41-1 to the n-th voltage generation circuit 41-n and outputs the sum. The output voltage of the addition circuit 42 becomes the output voltage of the temperature compensation circuit 40 (temperature compensation voltage).

The output circuit 20 receives the oscillation signal output from the oscillation circuit 10, generates an oscillation signal for an external output, and outputs the generated signal through the OUT terminal. For example, the division ratio and the output level of the oscillation signal in the output circuit 20 may be controlled by the control data stored in the register 74. An output frequency range of the oscillator 1 is, for example, 10 MHz or more and 800 MHz or less.

In a desired temperature range, irrespective of the temperature, the oscillator 1 configured as described above functions as a voltage controlled temperature compensated oscillator that outputs an oscillation signal having a constant frequency corresponding to the voltage of the external terminal VC 1. In particular, in a case where the resonator element 3 is the quartz crystal resonator element, the oscillator 1 functions as the voltage controlled temperature compensated crystal oscillator (VC-TCXO).

### 1.2. Method of Manufacturing Oscillator

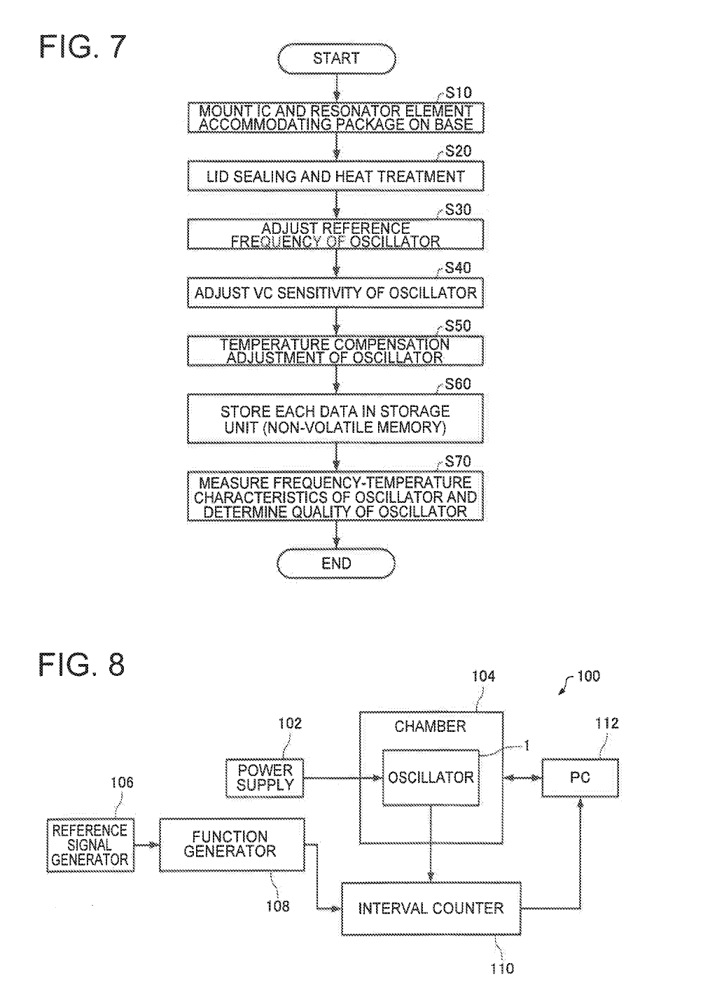

FIG. 7 is a flowchart showing an example of a procedure of a method of manufacturing the oscillator 1 according to the embodiment. A part of steps S10 to S70 in FIG. 7 may be omitted or changed, or another step may be added. The order of each step may be changed as necessary within a possible range.

In the example of FIG. 7, the integrated circuit (IC) 2 and a resonator element accommodating package which is the package 4 accommodating the resonator element 3 are first mounted on the base 8a (S10). In step S10, the integrated circuit (IC) 2 is connected to the external terminals 5a and 5b of the package 4, and when the power is supplied to the integrated circuit (IC) 2, the integrated circuit (IC) 2 and the resonator element 3 are connected electrically.

Next, the base 8a is sealed by the lid 8b, and heat treatment is performed to bond the lid 8b to the base 8a (S20). In step S20, the assembly of the oscillator 1 is completed.

Next, the reference frequency (frequency at the reference temperature T0 (for example, 25° C.)) of the oscillator 1 is adjusted (S30). In step S30, the oscillator 1 is oscillated at the reference temperature T0, the frequency is measured, and frequency adjustment data is determined such that the frequency deviation is close to zero.

Next, the voltage control (VC) sensitivity of the oscillator 1 is adjusted (S40). The VC sensitivity is the ratio of the change in the oscillation frequency to the change in the control voltage. In step S40, at the reference temperature T0, in a state where a predetermined voltage (for example, 0 V or VDD) is applied to the external terminal VC1, the oscillator 1 is oscillated, the oscillation frequency is measured, and adjustment data of the AFC circuit 32 is determined so as to obtain a desired VC sensitivity.

Next, the temperature compensation adjustment of the oscillator 1 is performed (S50). In the temperature compensation adjustment step S50, in a desired temperature range, the frequencies of the oscillator 1 at a plurality of temperatures are measured, the temperature compensation data (first compensation data, . . . , n-th compensation data) for correcting the frequency-temperature characteristic of the oscillator 1 is generated based on the measurement result. A desired temperature range is, for example, −40° C. or more and 85° C. or less. Specifically, using the measurement result of the frequencies at the plurality of temperatures, a program for calculating the temperature compensation data approximates the frequency-temperature characteristics (including frequency-temperature characteristics of resonator element 3 and temperature characteristics of the integrated circuit (IC) 2) of the oscillator 1 with an n-th equation in which a temperature (output voltage of the temperature sensor 50) is a variable. The temperature compensation data (first compensation data, . . . , n-th compensation data) corresponding to the approximation equation is generated. For example, the program for calculating the temperature compensation data sets the frequency deviation at the reference temperature T0 to zero, and generates the temperature compensation data (first compensation data, . . . , n-th compensation data) so as to reduce the width of the frequency deviation within a desired temperature range.

Next, each data obtained in steps S30, S40, and S50 is stored in the non-volatile memory 72 of the storage unit 70 (S60).

Finally, the frequency-temperature characteristics of the oscillator 1 is measured, and the quality of the oscillator 1 is determined (S70). In step S70, the frequency of the oscillator 1 is measured while gradually changing the temperature, and it is evaluated whether the frequency deviation is within a predetermined range in a desired temperature range (for example, −40° C. or more and 85° C. or less). It is determined as a non-defective when the frequency deviation is within the predetermined range, and it is determined as a defective when the frequency deviation is not within the predetermined range.

### 1.3. Wander Performance of Oscillator

### 1 About Wander

The wander refers to a fluctuation that varies at a frequency lower than 10 Hz among phase fluctuations of a frequency signal (oscillation signal) output from an oscillator. A typical evaluation amount representing the wander performance is maximum time interval error (MTIE) and time deviation (TDEV).

The MTIE refers to the peak to peak maximum value of a phase variation amount within an observation time τ when the observation result of the phase variation amount with respect to the reference clock is divided into an interval of the observation time τ. That is, the peak to peak maximum value of the phase variation amount with respect to the reference clock within the observation time τ becomes an MTIE value at the observation time τ.

The TDEV is a statistical amount corresponding to the effective value of the phase variation amount with respect to the reference clock. The TDEV is expressed by the following equation, where x(iτ₀) (i=1, 2, 3, . . . ) is the sample sequence of the observation time τ (where τ=nτ₀ (n=0, 1, 2, . . . )) and the time error x(t) of a data signal with respect to the reference timing.

$$TDEV ( n {τ}_{0} ) = {[ ( \frac{1}{6 {n}^{2}} ) 〈 {[ Σ \{ x ( i {τ}_{0} + 2 n {τ}_{0} ) - 2 x ( i {τ}_{0} + n {τ}_{0} ) + x ( i {τ}_{0} ) \} ]}^{2} 〉 ]}^{\frac{1}{2}} \qquad Formula 1$$

Where the bracket symbol < > represents the average value, the symbol Σ represents the sum of i=1 to n, n is an integer from 1 to N/3, and N is the total number of samples.

### 2 Measurement System

FIG. 8 is a diagram showing a measurement system 100 for evaluating the wander performance of the oscillator 1 (measuring MTIE value and TDEV value).

As shown in FIG. 8, the measurement system 100 includes the oscillator 1, a power supply 102, a chamber 104, a reference signal generator 106, a function generator 108, an interval counter 110, and a PC (personal computer) 112.

The configuration of the oscillator 1 used in the evaluation is as described in “1.1 Configuration of Oscillator” (refer to FIGS. 1 to 4). The space where the resonator element 3 of the package 4 is accommodated and the space where the integrated circuit (IC) 2 of the package 8 and the package 4 are accommodated are a nitrogen gas atmosphere. The resonator element 3 is the quartz crystal resonator element. The power supply voltage V_{cc}=3.3 V is supplied to the oscillator 1 from the power supply 102. The output frequency (nominal frequency) of the oscillator 1 is 19.2 MHz. The oscillator 1 is the CMOS output format, and the capacitive load is 15 pF.

The oscillator 1 is accommodated inside the chamber 104 capable of temperature control. The temperature inside the chamber 104 is controlled by the PC 112.

In the measurement system 100, the reference signal (the reference clock) is obtained by generating a frequency signal of 19.2 MHz which is the same as the output frequency of the oscillator 1 using the function generator 108 from the frequency signal of 10 MHz output from the reference signal generator 106.

The measured signal (frequency signal of oscillator 1) and the reference signal are input into the interval counter 110. In the interval counter 110, the phase variation amount of the measured signal with respect to the reference signal is measured, and the MTIE value and a TDEV value are calculated from the measurement result in the PC 112.

As a comparison example, a conventional temperature compensated crystal oscillator (comparison sample C1) is prepared, and the wander performance of the comparison sample C1 is also evaluated.

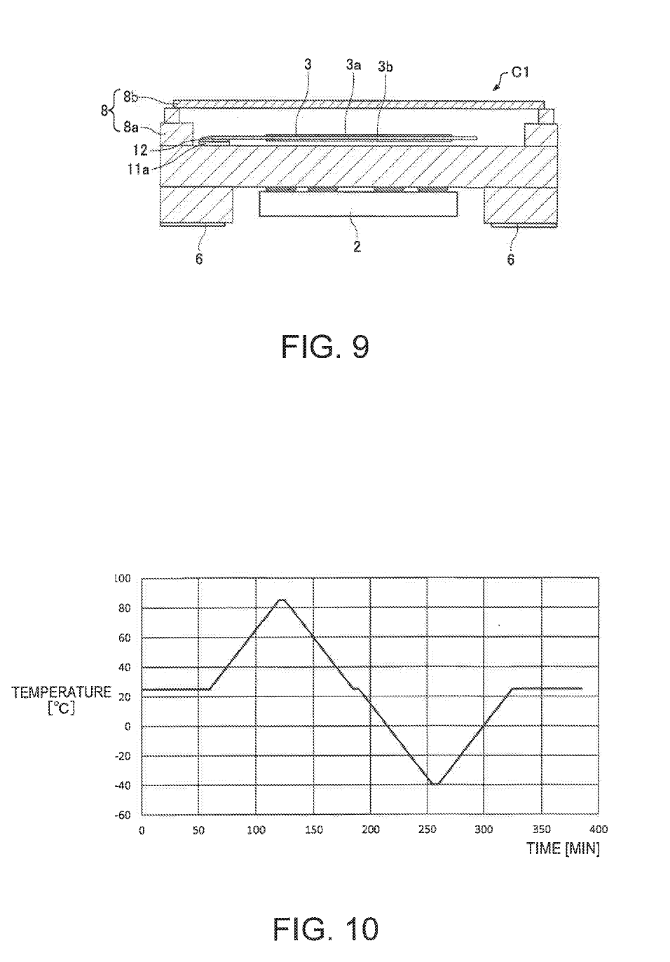

FIG. 9 is a cross-sectional view schematically showing a configuration of the comparison sample C1.

In the comparison sample C1, as shown in FIG. 9, the base 8a has an H-type structure in which recessed portions are disposed on two main surfaces, respectively. In the comparison sample C1, the resonator element 3 is accommodated in a recessed portion disposed on one main surface of the base 8a, and the integrated circuit (IC) 2 is accommodated in a recessed portion disposed on the other main surface of the base 8a. Other configurations of the comparison sample C1 are the same as the configurations of the oscillator 1.

### 3 Method of Evaluating Wander Performance

The wander performance of the oscillator 1 is evaluated in a case where the temperature inside the chamber 104 is varied using the measurement system 100 shown in FIG. 8.

The following Table 1 is a table showing a temperature profile of the chamber 104. FIG. 10 is a graph showing a temperature profile inside the chamber 104. The horizontal axis of the graph shown in FIG. 10 is time (minute), and the vertical axis is temperature inside the chamber 104.

Here, in the measurement system 100, the MTIE value and the TDEV value of the oscillator 1 are measured while varying the temperature inside the chamber 104 with the temperature profile shown in the following Table 1 and FIG. 10.

TABLE 1

| Time [min] | Temperature [° C.] |
|---|---|
| 0 → 60 | 25° C. |
| 60 → 120 | 25° C. → 85° C. (1° C./min) |
| 120 → 125 | 85° C. |
| 125 → 185 | 85° C. → 25° C. (1° C./min) |
| 185 → 190 | 25° C. |
| 190 → 255 | 25° C. → −40° C. (1° C./min) |
| 255 → 260 | −40° C. |
| 260 → 325 | −40° C. → 25° C. (1° C./min) |
| 325 → 385 | 25° C. |

As shown in Table 1 and FIG. 10, the temperature of the chamber 104 is constant at 25° C. from a measurement start (elapsed time of 0 minutes) to an elapsed time of 60 minutes. The temperature of the chamber 104 is raised from 25° C. to 85° C. at a heating rate of 1° C./min from an elapsed time of 60 minutes to 120 minutes. The temperature of the chamber 104 is constant at 85° C. from an elapsed time of 120 minutes to 125 minutes. The temperature of the chamber 104 is lowered from 85° C. to 25° C. at a cooling rate of 1° C./min from an elapsed time of 125 minutes to 185 minutes. The temperature of the chamber 104 is constant at 25° C. from an elapsed time of 185 minutes to 190 minutes. The temperature of the chamber 104 is lowered from 25° C. to −40° C. at the cooling rate of 1° C./min from an elapsed time of 190 minutes to 255 minutes. The temperature of the chamber 104 is constant at −40° C. from an elapsed time of 255 minutes to 260 minutes. The temperature of the chamber 104 is raised from −40° C. to 25° C. at the heating rate of 1° C./min from an elapsed time of 260 minutes to 325 minutes. The temperature of the chamber 104 is constant at 25° C. from an elapsed time of 325 minutes to 385 minutes. The MTIE value of the oscillator 1 is obtained by measuring the peak to peak maximum value of the phase variation amount with respect to the reference clock within the observation time τ in the elapsed time of 0 minutes to 385 minutes in Table 1 and FIG. 10. The TDEV value of the oscillator 1 is obtained by measuring the statistical amount corresponding to the effective value of the phase variation amount with respect to the reference clock based on Formula 1 in the elapsed time of 0 minutes to 385 minutes in Table 1 and FIG. 10.

The same measurement is performed also for the comparison sample C1.

### 4 Evaluation Result of Wander Performance

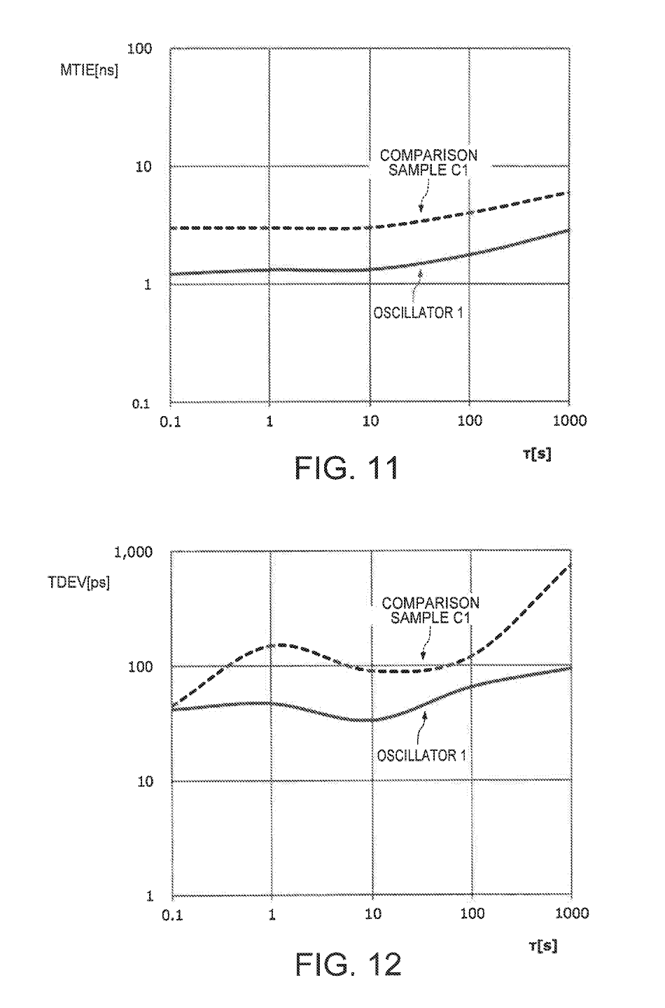

FIGS. 11 and 12 are graphs showing an evaluation result of the wander performance of the oscillator 1 and the comparison sample C1 in the case where the temperature inside the chamber 104 is varied with the temperature profile shown in Table 1 and FIG. 10. FIG. 11 is the graph showing the measurement result of the MTIE value, and FIG. 12 is the graph showing the measurement result of the TDEV value. The horizontal axis of the graph shown in FIG. 11 is the observation time τ (second), and the vertical axis is the MTIE value (10⁻⁹ seconds). The horizontal axis of the graph shown in FIG. 12 is the observation time τ (second), and the vertical axis is the TDEV value (10⁻¹² seconds).

The following Table 2 is a table showing the MTIE value of the oscillator 1 and the comparison sample C1 at τ=0.1 s (second), τ=1 s, τ=10 s, τ=100 s, τ=1000 s. The following Table 3 is a table showing the TDEV value of the oscillator 1 and the comparison sample C1 at τ=0.1 s (second), τ=1 s, τ=10 s, τ=100 s, τ=1000 s.

TABLE 2

| | MTIE value of oscillator 1 | MTIE value of comparison |
|---|---|---|
| τ [s] | [ns] | sample C1 [ns] |
| 0.1 | 1.2 | 3.0 |
| 1 | 1.3 | 3.0 |
| 10 | 1.3 | 3.0 |
| 100 | 1.8 | 4.0 |
| 1000 | 2.9 | 6.0 |

TABLE 3

| | TDEV value of oscillator 1 | TDEV value of comparison |
|---|---|---|
| τ [s] | [ps] | sample C1 [ps] |
| 0.1 | 42 | 45 |
| 1 | 47 | 150 |
| 10 | 33.4 | 90 |
| 100 | 65 | 120 |
| 1000 | 94 | 750 |

As shown in Table 2 and FIG. 11, in the case where the temperature inside the chamber 104 is varied with the temperature profile shown in Table 1 and FIG. 10, in the oscillator 1, the MTIE value at 0.1 s<τ≤1 s is 1.3 ns or less, the MTIE value at 1 s<τ≤10 s is 1.3 ns or less, the MTIE value at 10 s<τ≤100 s is 1.8 ns or less, and the MTIE value at 100 s<τ≤1000 s is 2.9 ns or less. As shown in Table 3 and FIG. 12, in the case where the temperature inside the chamber 104 is varied with the temperature profile shown in Table 1 and FIG. 10, in the oscillator 1, the TDEV value at 0.1 s<τ≤10 s is 47 ps or less, the TDEV value at 10 s<τ≤100 s is 65 ps or less, and the TDEV value at 100 s<τ≤1000 s is 94 ps or less. The oscillator 1 satisfying the conditions of the MTIE values and the TDEV values has the excellent wander performance as compared with the comparison sample C1. It is possible to further improve the wander performance of the oscillator 1 by setting an MTIE value at 0 s<τ≤0.1 s to 1.2 ns or less and a TDEV value at 0 s<τ≤0.1 s to 42 ps or less in addition to the conditions of the MTIE values and the TDEV values.

The oscillator 1 according to the embodiment has, for example, the following features.

In the oscillator 1, in the case of the temperature profile shown in Table 1 and FIG. 10, that is, in the case where the temperature of the chamber 104 is constant at 25° C. from a measurement start to an elapsed time of 60 minutes, is raised from 25° C. to 85° C. at the heating rate of 1° C./min from an elapsed time of 60 minutes to 120 minutes, is constant at 85° C. from an elapsed time of 120 minutes to 125 minutes, is lowered from 85° C. to 25° C. at the cooling rate of 1° C./min from an elapsed time of 125 minutes to 185 minutes, is constant at 25° C. from an elapsed time of 185 minutes to 190 minutes, is lowered from 25° C. to −40° C. at the cooling rate of 1° C./min from an elapsed time of 190 minutes to 255 minutes, is constant at −40° C. from an elapsed time of 255 minutes to 260 minutes, is raised from −40° C. to 25° C. at the heating rate of 1° C./min from an elapsed time of 260 minutes to 325 minutes, and is constant at 25° C. from an elapsed time of 325 minutes to 385 minutes, the MTIE value at 0.1 s<τ≤1 s is 1.3 ns or less, the MTIE value at 1 s<τ≤10 s is 1.3 ns or less, the MTIE value at 10 s<τ≤100 s is 1.8 ns or less, and the MTIE value at 100 s<τ≤1000 s is 2.9 ns or less. Further, in the oscillator 1, in the case where the temperature inside the chamber 104 is varied with the temperature profile shown in Table 1 and FIG. 10, the TDEV value at 0.1 s<τ≤10 s is 47 ps or less, the TDEV value at 10 s<τ≤100 s is 65 ps or less, and the TDEV value at 100 s<τ≤1000 s is 94 ps or less.

Here, the wander performance in the case of a constant temperature is defined in the ITU-T recommendation G.813. In the oscillator 1, the wander performance in the case where the temperature inside the chamber 104 is varied with the temperature profile shown in Table 1 and FIG. 10 satisfies the wander performance in the case of the constant temperature defined in the ITU-T recommendation G.813. As described above, the oscillator 1 has the excellent wander performance even under the environment where the temperature varies. Consequently, the oscillator 1 can be used for an electronic device and a vehicle that are required to have high frequency stability even under the severe temperature environment.

Since the oscillator 1 has the excellent wander performance even under the severe temperature environment compared with the conventional temperature compensated crystal oscillator (comparison sample C1), for example, when the oscillator 1 is used for a communication device or the like as described below, the communication device with the excellent communication performance can be realized even under the severe temperature environment. For example, the oscillator 1 can be employed to an electronic device and a vehicle that are required to have high frequency stability in such a case where an oven-controlled crystal oscillator (OCXO) is used. Consequently, miniaturization and e and power-saving of the electronic device and the vehicle can be achieved.

In the oscillator 1, the lid 4b of the package 4 is bonded to the package 8 (the base 8a). Accordingly, in the oscillator 1, it is possible to dispose the integrated circuit (IC) 2 on the second surface 15b of the base 4a and reduce the temperature difference between the integrated circuit (IC) 2 and the resonator element 3, that is, the temperature difference between the temperature sensor 50 and the resonator element 3 as described above. Consequently, in the oscillator 1, an error in the temperature compensation by the temperature compensation circuit 40 becomes small, so that the excellent wander performance described above can be realized.

In the oscillator 1, the package 4 has the first surface 15a and the second surface 15b opposite to the first surface 15a, the resonator element 3 is disposed on the first surface 15a, and the integrated circuit (IC) 2 including the oscillation circuit 10, the temperature compensation circuit 40, and the temperature sensor 50 is disposed on the second surface 15b. Consequently, the temperature difference between the integrated circuit (IC) 2 and the resonator element 3 can be reduced.

In the oscillator 1, the resonator element 3 is positioned between the lid 4b of the package 4 and the lid 8b of the package 8. Accordingly, in the oscillator 1, the lid 4b and the lid 8b are made of, for example, a metal, so that the lid 4b and the lid 8b can function as a shield for shielding an external electromagnetic noise. Consequently, it is possible to reduce the influence of the noise with respect to the resonator element 3.

In the oscillator 1, the integrated circuit (IC) 2 and the external terminals 5a and 5b are disposed on the second surface 15b of the base 4a. Accordingly, in the oscillator 1, the external terminals 5a and 5b can be separated from the base 8a (bottom surface of recessed portion) of the package 8, and the influence of the external noise can be reduced. Further, in the oscillator 1, the external terminals 5a and 5b are disposed on the second surface 15b of the base 4a, so that a wire length between the resonator element 3 and the integrated circuit (IC) 2 can be reduced, and the influence of the noise can be reduced. For example, in a case where the resonator element 3 and the integrated circuit (IC) 2 are connected to each other electrically through the wires disposed inside the base 8a of the package 8 or on the surface of the recessed portion, the wire length becomes long, and it is susceptible to the influence of the noise.

### 1.4. Modification Example of Oscillator

Next, modification examples of the oscillator according to the embodiment will be described.

### 1 First Modification Example

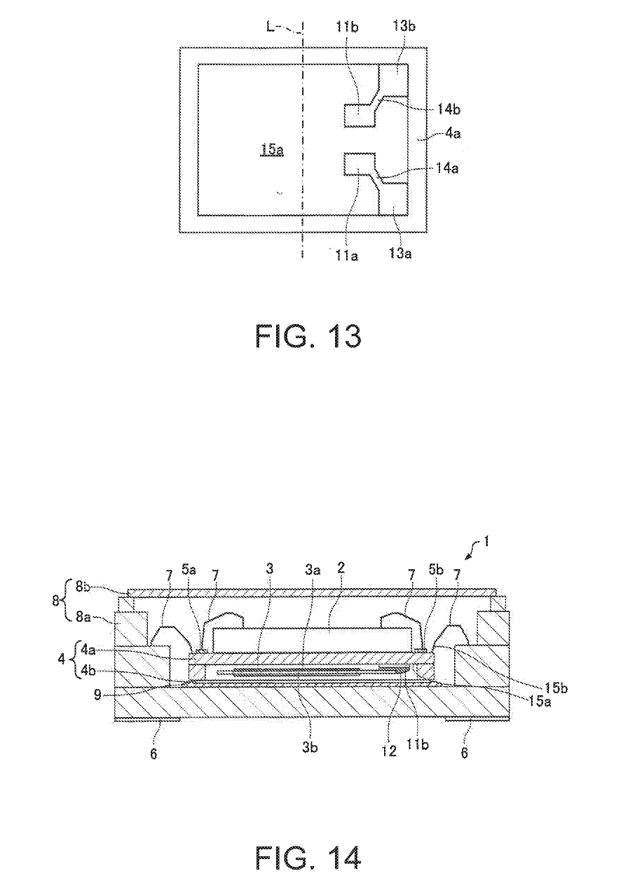

FIG. 13 is a plan view schematically showing the base 4a of the package 4 of an oscillator according to a first modification example. FIG. 13 corresponds to the FIG. 5.

In the oscillator according to the first modification example, as shown in FIG. 13, the disposition of the electrode pads 11a and 11b, the electrode pads 13a and 13b, and the lead-out wires 14a and 14b disposed on the base 4a is different from the disposition shown in FIG. 5 described above. Hereinafter, the difference will be described, and a description of the similar points will be omitted.

As shown in FIG. 13, in a plan view, when a virtual straight line L passing through the center of the base 4a and bisecting the base 4a is drawn, the electrode pad 13a and the electrode pad 13b are positioned on a side where the electrode pad 11a and the electrode pad 11b are disposed with respect to the virtual straight line L. Accordingly, the difference between the length of the lead-out wire 14a and the length of the lead-out wire 14b can be reduced as compared with the disposition shown in FIG. 5. In the shown example, the length of the lead-out wire 14a is equal to the length of the lead-out wire 14b.

In the oscillator according to the first modification example, in a plan view, when the virtual straight line L passing through the center of the base 4a and bisecting the base 4a is drawn, the electrode pad 13a and the electrode pad 13b are positioned on the side where the electrode pad 11a and the electrode pad 11b are disposed with respect to the virtual straight line L. Accordingly, the difference between the length of the lead-out wire 14a and the length of the lead-out wire 14b can be reduced. Consequently, it is possible to reduce the difference between a path length of the path through which the heat from the outside of the package 4 is transmitted to the resonator element 3 through the electrode pad 13a, the lead-out wire 14a, and the electrode pad 11a, and a path length of the path through which the heat is transmitted to the resonator element 3 through the electrode pad 13b, the lead-out wire 14b, and the electrode pad 11b.

As a result, for example, it is possible to reduce more the temperature unevenness of the resonator element 3 and the temperature difference between the integrated circuit (IC) 2 and the resonator element 3 as compared with the example of the oscillator 1 shown in FIG. 5 described above. According to the first modification example, therefore, the oscillator having the excellent wander performance as compared with the wander performance of the oscillator 1 shown in FIGS. 11 and 12 described above can be realized.

### 2 Second Modification Example

In the embodiment described above, the space accommodating the resonator element 3 of the package 4 and the space accommodating the integrated circuit (IC) 2 and the package 4 of the package 8 are the nitrogen gas atmosphere, but the spaces may be a helium gas atmosphere. Since the helium gas has high thermal conductivity as compared with the nitrogen gas, it is possible to reduce more the temperature difference between the integrated circuit (IC) 2 (temperature sensor 50) and the resonator element 3. According to the modification example, as a result, the oscillator having the excellent wander performance as compared with the wander performance of the oscillator 1 shown in FIGS. 11 and 12 described above can be realized.

The space accommodating the resonator element 3 of the package 4 may be the inert gas atmosphere such as nitrogen gas or helium gas, and the space inside the package 8 accommodating the integrated circuit (IC) 2 and the package 4 may be a vacuum. Here, the vacuum is a state where a pressure inside a space is lower than the atmospheric pressure. Consequently, it is possible to reduce the temperature difference between the integrated circuit (IC) 2 and the resonator element 3, and the influence of the temperature variation outside the package 8 on the integrated circuit (IC) 2 and the resonator element 3. As a result, according to the modification example, the oscillator having the excellent wander performance as compared with the wander performance of the oscillator 1 shown in FIGS. 11 and 12 described above can be realized.

### 3 Third Modification Example

FIG. 14 is a cross-sectional view schematically showing an oscillator 1 according to a third modification example. FIG. 14 corresponds to FIG. 2.

In the oscillator according to the third modification example, as shown in FIG. 14, the external terminals 5a and 5b and the terminals of the integrated circuit (IC) 2 disposed on the second surface 15b of the base 4a are connected to each other by the bonding wire 7, which is different from the oscillator shown in FIG. 2 described above. Hereinafter, the difference will be described, and a description of the similar points will be omitted.

As shown in FIG. 14, even in the case where the external terminals 5a and 5b and the terminals of the integrated circuit (IC) 2 are connected to each other by the bonding wire 7, similarly to the example shown in FIG. 2 described above, the wire length between the resonator element 3 and the integrated circuit (IC) 2 can be reduced.

In the example shown in FIG. 2, each terminal of the integrated circuit (IC) 2 is bonded directly to the wires disposed in the base 8a (wires electrically connected to each external terminal 6) by the bonding wire 7. In contrast, in the example shown in FIG. 14, each terminal of the integrated circuit (IC) 2 is connected to the wires disposed in the base 8a through wires (not shown) disposed on the second surface 15b of the base 4a. Specifically, wires connected to each terminal of the integrated circuit (IC) 2 is disposed on the second surface 15b of the base 4a, and the wires are connected to the wires disposed in the base 8a by the bonding wire 7.

According to the modification example, it is possible to obtain the same operational effect as the oscillator 1 shown in FIG. 2 described above.

### 2. Electronic Device

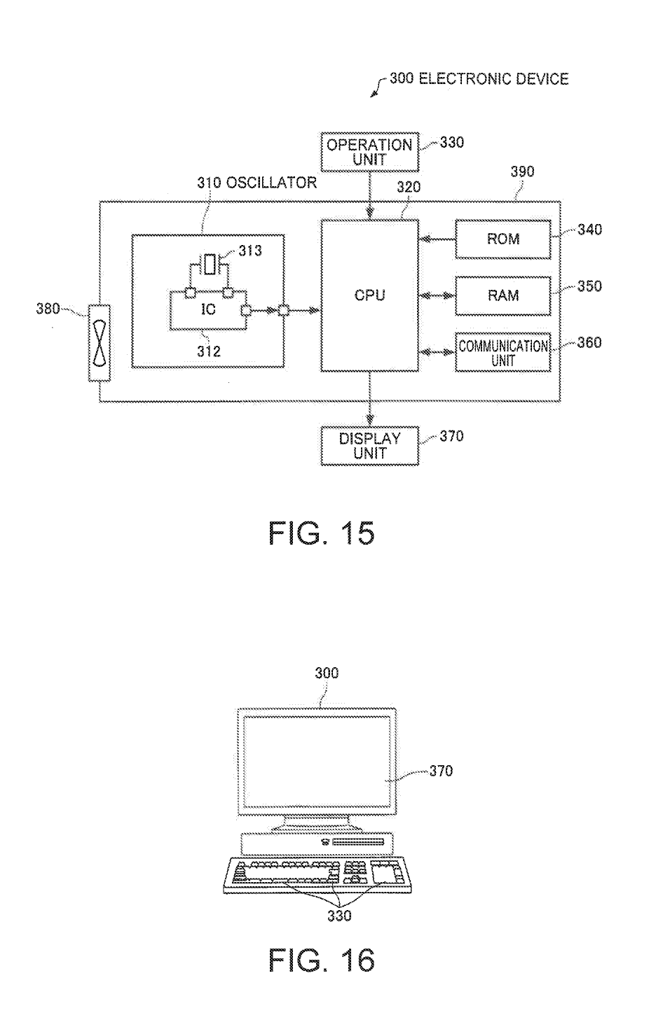

FIG. 15 is a functional block diagram showing an example of a configuration of an electronic device according to the embodiment. FIG. 16 is a diagram showing an example of the external appearance of the personal computer as an example of the electronic device according to the embodiment.

An electronic device 300 according to the embodiment is configured to have an oscillator 310, a central processing unit (CPU) 320, an operation unit 330, a read only memory (ROM) 340, a random access memory (RAM) 350, a communication unit 360, a display unit 370, and a cooling fan 380. In the electronic device according to the embodiment, a part of the configuration elements (each portion) of FIG. 15 may be omitted or changed, or another configuration element may be added.

The oscillator 310 includes the integrated circuit (IC) 312 and a resonator element 313. The integrated circuit (IC) 312 oscillates the resonator element 313 and generates an oscillation signal. The oscillation signal is output from an external terminal of the oscillator 310 to the CPU 320.

The CPU 320 performs various calculation processing and control processing with the oscillation signal input from the oscillator 310 as a clock signal in response to a program stored in ROM 340 or the like. Specifically, the CPU 320 performs various processing in response to an operation signal from the operation unit 330, processing for controlling the communication unit 360 to perform data communication with an external apparatus, and processing for transmitting a display signal to display various pieces of information on the display unit 370.

The operation unit 330 is an input apparatus configured to have an operation key, a button switch, and the like, and outputs an operation signal in response to an operation by a user to the CPU 320.

The ROM 340 stores a program, data, and the like for the CPU 320 to perform various calculation processing and control processing.

The RAM 350 is used as a work region of the CPU 320 and temporarily stores a program and data read from the ROM 340, data input from the operation unit 330, and a calculation result or the like executed by the CPU 320 in response to various programs.

The communication unit 360 performs various controls for establishing data communication between the CPU 320 and the external apparatus.

The display unit 370 is a display apparatus configured to have a liquid crystal display (LCD) or the like and displays various pieces of information based on a display signal input from the CPU 320. A touch panel functioning as the operation unit 330 may be provided on the display unit 370.

The cooling fan 380 is mounted on a housing 390 accommodating the oscillator 310, the CPU 320, the ROM 340, RAM 350, and the communication unit 360. The cooling fan 380 cools the inside of the housing 390. The cooling fan 380 is, for example, a fan that takes in the air outside the housing 390 (outside air) and blows the air into the housing 390. In the shown example, the housing 390 includes one cooling fan 380, but the housing 390 may include a plurality of cooling fans 380.

As the oscillator 310, an electronic device including an oscillator having the excellent wander performance even under the severe temperature environment can be realized by employing the oscillator 1 described above. In particular, even in a case where an electronic device includes the cooling fan 380, and the oscillator 310 is blown with the wind by an operation of the cooling fan 380, it is possible to realize the electronic device having high performance and high reliability by employing the oscillator 1 having the excellent wander performance as the oscillator 310.

Such an electronic device 300 is exemplified by various electronic devices such as a personal computer (for example, mobile personal computer, laptop personal computer, and tablet personal computer), a mobile terminal such as smartphone or mobile phone, a digital camera, an ink jet ejection apparatus (for example, ink jet printer), a storage area network device such as router or switch, local area network device, a mobile terminal base station device, television, a video camera, a video recorder, a car navigation apparatus, a real time clock apparatus, a pager, an electronic organizer (including communication function included), an electronic dictionary, a calculator, an electronic game apparatus, a game controller, a word processor, a workstation, a video telephone, a security monitor, an electronic binocular, a point of sale (POS) terminal, a medical device (for example, electronic thermometer, blood pressure meter, blood glucose meter, electrocardiogram measurement apparatus, ultrasonic diagnostic apparatus, and electronic endoscope), a fish finder, various measurement devices, an instrument (for example, instrument of vehicle, airplane, or ship), a flight simulator, a head mount display, a motion tracer, a motion tracking, a motion controller, a pedestrian dead reckoning (PDR).

As an example of the electronic device 300 according to the embodiment, for example, a transmission apparatus functioning as a terminal base station apparatus that performs wired or wireless communication with a terminal is exemplified by using the oscillator 310 described above as a reference signal source, a voltage-controlled oscillator (VCO), or the like. It is possible to realize, for example, an electronic device which is usable for a communication base station or the like and which is desired to have high performance and high reliability by employing the oscillator 1 as the oscillator 310.

As another example of the electronic device 300 according to the embodiment, a communication apparatus including a frequency control unit in which the communication unit 360 receives an external clock signal, and the CPU 320 (processing unit) controls a frequency of the oscillator 310 based on the external clock signal and the output signal of the oscillator 310 (internal clock signal) is exemplified. The communication apparatus, for example, may be a basic system network device such as stratum 3 or a communication device used for a femtocell.

### 3. Vehicle

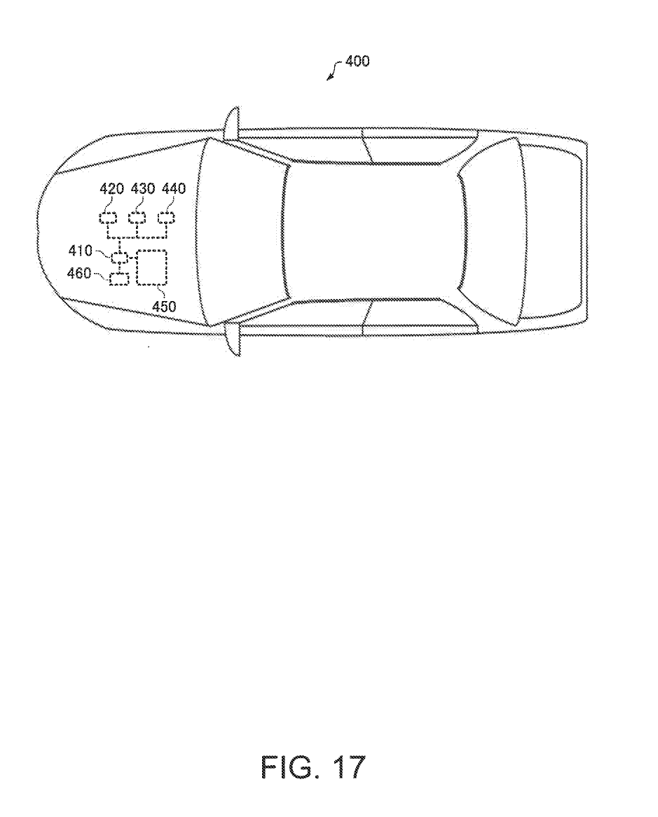

FIG. 17 is a diagram (top view) showing an example of a vehicle according to the embodiment. The vehicle 400 shown in FIG. 17 is configured to have an oscillator 410, controllers 420, 430, and 440 that perform various controls of an engine system, a brake system, a keyless entry system, and the like, a battery 450, and a backup battery 460. In the vehicle according to the embodiment, a part of the configuration elements (each portion) of FIG. 17 may be omitted, or another configuration element may be added.

The oscillator 410 includes an integrated circuit (IC) and a resonator element (not shown), and the integrated circuit (IC) oscillates the resonator element and generates an oscillation signal. The oscillation signal is output from an external terminal of the oscillator 410 to controllers 420, 430, and 440 and is used, for example, as a clock signal.

The battery 450 supplies power to the oscillator 410 and the controllers 420, 430, and 440. When the output voltage of the battery 450 is lower than a threshold value, the backup battery 460 supplies the power to the oscillator 410 and the controllers 420, 430, and 440.

A vehicle including an oscillator having the excellent wander performance even under the severe temperature environment can be realized by employing the oscillator 1 described above as the oscillator 410.

Such vehicle 400 is exemplified by various vehicles such as a vehicle (including electric vehicle), an airplane such as a jet plane or a helicopter, a ship, a rocket, an artificial satellite.

The embodiments and modification examples described above are only examples, and the invention is not limited to the examples. For example, it is possible to combine each embodiment and each modification example as necessary.

The invention includes substantially the same configuration (for example, configuration having the same function, method, and result or configuration having the same purpose and effect) as the configuration described in the embodiments. The invention includes a configuration in which a non-essential portion of the configuration described in the embodiments is replaced. The invention includes a configuration in which the same operational effect as the configuration described in the embodiments is obtained, or a configuration in which the same purpose can be achieved. The invention includes a configuration to which a known technique is added to the configuration described in the embodiments.

What is claimed is:

1. A temperature compensated oscillator comprising:
a resonator element;
an oscillation circuit; and
a temperature compensation circuit,
wherein when a temperature is constant at 25° C. from a measurement start to an elapsed time of 60 minutes,
is raised from 25° C. to 85° C. at a heating rate of 1° C./min from an elapsed time of 60 minutes to 120 minutes,
is constant at 85° C. from an elapsed time of 120 minutes to 125 minutes,
is lowered from 85° C. to 25° C. at a cooling rate of 1° C./min from an elapsed time of 125 minutes to 185 minutes,
is constant at 25° C. from an elapsed time of 185 minutes to 190 minutes,
is lowered from 25° C. to −40° C. at the cooling rate of 1° C./min from an elapsed time of 190 minutes to 255 minutes,
is constant at −40° C. from an elapsed time of 255 minutes to 260 minutes,
is raised from −40° C. to 25° C. at the heating rate of 1° C./min from an elapsed time of 260 minutes to 325 minutes, and
is constant at 25° C. from an elapsed time of 325 minutes to 385 minutes,
at an observation time of τ, a maximum time interval error (MTIE) value includes:
an MTIE value at 0.1 s<τ≤1 s is 1.3 ns or less,
an MTIE value at 1 s<τ≤10 s is 1.3 ns or less,
an MTIE value at 10 s<τ≤100 s is 1.8 ns or less,
an MTIE value at 100 s<τ≤1000 s is 2.9 ns or less, and
at the observation time of τ, a time deviation (TDEV) value includes:
a TDEV value at 0.1 s<τ≤10 s is 47 ps or less,
a TDEV value at 10 s<τ≤100 s is 65 ps or less, and
a TDEV value at 100 s<τ≤1000 s is 94 ps or less.

2. The temperature compensated oscillator according to claim 1, further comprising:
a first container that accommodates the resonator element; and
a second container that accommodates the first container, the oscillation circuit, and the temperature compensation circuit,
wherein the first container has a first base in which the resonator element is disposed and a first lid, and
wherein the first lid is bonded to the second container.

3. The temperature compensated oscillator according to claim 2,
wherein the temperature compensation circuit compensates for frequency-temperature characteristics of the resonator element based on an output signal of a temperature sensor,
wherein the first base has a first surface on which the resonator element is disposed and a second surface opposite to the first surface, and
wherein an electronic component including the oscillation circuit, the temperature compensation circuit, and the temperature sensor is disposed on the second surface.

4. The temperature compensated oscillator according to claim 3,
wherein a terminal that is connected electrically to the resonator element is disposed on the second surface.

5. The temperature compensated oscillator according to claim 2,
wherein the second container has a second base and a second lid, and
wherein the resonator element is positioned between the first lid and the second lid.

6. The temperature compensated oscillator according to claim 2,
wherein a space inside the second container is a vacuum.

7. An electronic device comprising:
the temperature compensated oscillator according to claim 1; and
a cooling fan.

8. An electronic device comprising:
the temperature compensated oscillator according to claim 2; and
a cooling fan.

9. An electronic device comprising:
the temperature compensated oscillator according to claim 3; and
a cooling fan.

10. An electronic device comprising:
the temperature compensated oscillator according to claim 4; and
a cooling fan.

11. An electronic device comprising:
the temperature compensated oscillator according to claim 5; and
a cooling fan.

12. An electronic device comprising:
the temperature compensated oscillator according to claim 6; and
a cooling fan.

13. A temperature compensated oscillator comprising:
a resonator element;
an oscillation circuit;
a memory;
a temperature sensor; and
a temperature compensation circuit that receives an output signal from the temperature sensor, generates a voltage for correcting frequency-temperature characteristic of the resonator element, and applies the generated voltage to the oscillation circuit, the temperature compensation circuit comprising:
a plurality of voltage generation circuits including a first voltage generation circuit to an n-th voltage generation circuits, n being an integer greater than 1; and
an addition circuit,
wherein the first voltage generation circuit to the n-th voltage generation circuit respectively receive the output signal from the temperature sensor, generates a first compensation voltage to an n-th compensation voltage for compensating a first component to an n-th component of the frequency-temperature characteristics corresponding to first compensation data to n-th compensation data stored in the memory,
the addition circuit adds the first compensation voltage to the n-th compensation voltage respectively generated by the first voltage generation circuit to the n-th voltage generation circuit and outputs a sum of the added voltages to the oscillation circuit.
